(19) United States
(12) Patent Application Publication
(10) Pub. No.: US 2026/0194884 A1
(43) Pub. Date: Jul. 9, 2026

(54) MATERIAL SELECTION APPARATUS AND METHOD FOR VEHICLE PARTS USING A BRS (BUZZ, RATTLE, SQUEAK) NOISE PREDICTION ALGORITHM

(71) Applicants: HYUNDAI MOTOR COMPANY, Seoul (KR); KIA CORPORATION, Seoul (KR); KOREA UNIVERSITY RESEARCH & BUSINESS FOUNDATION, Seoul (KR)

(72) Inventors: Kyung Woo Lee, Hwaseong-si (KR); Dae Un Sung, Hwaseong-si (KR); Seong Ho Yoon, Seoul (KR); Jun Young Yoon, Seoul (KR); Byoung Ho Choi, Seoul (KR); Sang Min Lee, Seoul (KR)

(73) Assignees: HYUNDAI MOTOR COMPANY, Seoul (KR); KIA CORPORATION, Seoul (KR); KOREA UNIVERSITY RESEARCH & BUSINESS FOUNDATION, Seoul (KR)

(21) Appl. No.: 19/326,657

(22) Filed: Sep. 11, 2025

(30) Foreign Application Priority Data
Jan. 9, 2025 (KR) 10-2025-0003396

(51) Int. Cl. G05B 19/418

(52) U.S. Cl. CPC G05B 19/4183; G05B 2219/49301

(57) ABSTRACT

A material selection method using an optimized machine learning prediction model that learns the correlation between materials and environmental factors includes acquiring material properties, test conditions, and BRS noise data required for model training, generating a Gaussian process regression model using Bayesian optimization based on the training data, predicting an affective quality index for each dissimilar material using the model, and selecting an optimal material by synthesizing the indices. The optimal material may be selected based on predicting a BRS noise signal and an affective quality index value that may occur for each condition through a machine learning model, identifying the principle of BRS noise occurrence, and identifying the range of material properties and environmental factors in a training database according to the design criteria using a predicted value of the machine learning model.

### CROSS-REFERENCE TO RELATED APPLICATION

This application claims the benefit of and priority to Korean Patent Application No. 10-2025-0003396, filed on Jan. 9, 2025, the entire contents of which are hereby incorporated herein by reference.

### BACKGROUND

### Technical Field

The present disclosure relates to a material selection apparatus and method for vehicle parts using a BRS (Buzz, Rattle, Squeak) noise prediction algorithm. More particularly, the present disclosure relates to a material selection apparatus and method for vehicle parts using an optimized machine learning algorithm.

### Discussion of the Related Art

In the past, the basic performance of vehicles, such as driving, braking, or steering, was considered an important development task, and the performance of vehicles was determined based on these indices. However, as technology applied to vehicles has developed, the basic performance of vehicles has reached a certain level, and vehicles with this performance are being mass-produced.

Due to the nature of vehicles driving on the road through various mechanical devices and parts such as a driving system, generation of an engine sound, a vibration sound of the driving system, and aerodynamic noise is inevitable. On the other hand, the quietness of vehicles is an important factor for customers when choosing products.

Vehicle research and development and evaluation are being conducted from the perspective of actual vehicle users, moving away from the past vehicle performance judgment criteria. Specifically, there is growing interest in technology that provides a comfortable riding environment for passengers.

Recently, with development of NVH (noise, vibration, and harshness) reduction technology and popularization of eco-friendly vehicles such as hybrid electric vehicles (HEVs) and electric vehicles (EVs), which use quiet motors and batteries instead of the main noise sources of cars, namely, engines and transmissions, the issue of BSR (buzz, squeak, and rattle) has been exposed. As eco-friendly cars gain popularity in the future, it is anticipated that these problems will become of greater importance.

An unwanted noise and a BRS noise may occur in vehicle parts due to vehicle behavior. These noises are difficult to understand because various factors in materials and the environment affect each other and interact in a complex manner, and improvements are insufficient.

### SUMMARY

Embodiments of the present disclosure provide a material selection apparatus and method for vehicle parts using a BRS noise prediction algorithm that substantially obviates one or more problems due to limitations and disadvantages of the related art.

Embodiments of the present disclosure provide a BRS noise prediction model through a machine learning algorithm that has learned the correlation between car parts and environmental factors and a generated BRS noise.

Further embodiments of the present disclosure provide a material selection apparatus and method for vehicle parts capable of selecting the optimal material through an optimized machine learning algorithm.

Further embodiments of the present disclosure provide a material selection apparatus and method for vehicle parts with an algorithm capable of predicting a BRS noise generated according to factors and conditions and an affective quality value and evaluating the importance of various factors.

According to an aspect of the present disclosure, a material selection apparatus for vehicle parts using a BRS noise prediction algorithm is provided. The material selection apparatus includes an input unit configured to receive an external input signal for setting various conditions. The material selection apparatus also includes a physical property data acquisition unit configured to acquire physical property information of a rubber material through various tests. The material selection apparatus additionally includes a BRS noise data acquisition unit configured to acquire BRS noise data due to friction between the rubber material and a dissimilar material while changing a surface shape, friction velocity, and friction load of the rubber material for vehicle parts. The material selection apparatus further includes a controller configured to control the physical property data acquisition unit and the BRS noise data acquisition unit according to test conditions input through the input unit, and to select an optimal rubber material using a Gaussian process regression model. The material selection apparatus also includes a display unit configured to display information according to a result of operation of the controller. The material selection apparatus additionally includes a storage unit configured to store information acquired through the input unit, the physical property data acquisition unit, and the BRS noise data acquisition unit and information associated with the Gaussian process regression model.

In an embodiment, the physical property data acquisition unit may include at least one of a surface roughness measurement device configured to measure roughness of a surface of the rubber material, a tensile force measurement device configured to measure mechanical properties of the rubber material, a contact angle measurement device configured to measure a contact angle for comparing free energy of the surface of the rubber material, or a dynamic mechanical analysis device configured to measure dynamic properties of the surface of the rubber material.

In an embodiment, the BRS noise data acquisition unit may include a velocity application configured to generate horizontal friction between the rubber material and the dissimilar material, a load application configured to generate vertical friction between the rubber material and the dissimilar material, a microphone configured to measure sound generated between the rubber material and the dissimilar material by frictional force that is changed and provided by the velocity application portion and/or the load application portion, and an accelerometer configured to measure vibration generated between the rubber material and the dissimilar material by the frictional force that is changed and provided by the velocity application portion and/or the load application portion.

In an embodiment, the dissimilar material may include at least one of aluminum, glass fiber reinforced plastic, or carbon fiber reinforced plastic.

In an embodiment, the controller may determine psychoacoustic annoyance, which is an affective quality index for each dissimilar material, based on the BRS noise data provided by the BRS noise data acquisition unit and may reflect the psychoacoustic annoyance in output data of the model.

In an embodiment, the controller may acquire an affective quality index value for each material using a machine learning algorithm including a Gaussian process regression model or a deep learning algorithm including a deep neural network.

In another aspect of the present disclosure, a material selection method for vehicle parts using a BRS noise prediction algorithm is provided. The material selection method includes acquiring training data to train a BRS noise prediction model of a material. The material selection method also includes generating a Gaussian process regression model using Bayesian optimization for the acquired training data. The material selection method additionally includes extracting affective quality index predicted values for respective dissimilar materials using the generated model. The material selection method further includes selecting an optimal material based on the affective quality index predicted values.

In an embodiment, acquiring data required to train the BRS noise prediction model may include performing a test for acquiring physical property information of a rubber material, and performing a test for acquiring friction noise data for a dissimilar material.

In an embodiment, the test for acquiring physical property information may for measuring the mechanical properties of the rubber material using a method standardized through tensile experiments, a test for measuring the surface roughness of the rubber material, a test for measuring the contact angle for comparing free energy of the surface of the rubber material for vehicle parts, and a test for measuring the dynamic properties of the surface of rubber material for vehicle parts.

In an embodiment, the dissimilar material may include at least one of aluminum, glass fiber reinforced plastic, or carbon fiber reinforced plastic.

In an embodiment, the test for acquiring annoying friction noise data for the dissimilar material may include acquiring noise and vibration data generated upon friction between the rubber material and the dissimilar material while changing the surface shape, friction velocity, and friction load of the rubber material, determining psychoacoustic characteristics, which are perceptual characteristics for auditory stimuli, using the acquired noise data, and combining the psychoacoustic characteristics to determine an affective quality index.

In an embodiment, the psychoacoustic characteristics may include at least one of loudness, sharpness, fluctuation, or roughness of sound.

In an embodiment, generating the Gaussian process regression model may include receiving the acquired training data, setting hyperparameters, generating a Gaussian process regression temporary model based on the set hyperparameters, receiving test data, applying the test data to the temporary model to determine whether the temporary model has reached an optimal point of an objective function, and returning to setting the hyperparameters again through search of a design space of the hyperparameters when the temporary model has not reached the optimal point and confirming the temporary model that reaches the optimal point as a BRS noise prediction machine learning model.

In an embodiment, extracting the affective quality index predicted values for respective dissimilar materials may include acquiring material property information of a plurality of candidate rubber materials, acquiring environmental factors considering conditions of use, determining a comprehensive affective quality index based on a plurality of affective quality indices for each dissimilar material, and selecting an optimal material based on the comprehensive affective quality index for each of the plurality of candidate rubber materials.

It should be understood that both the foregoing general description and the following detailed description of the present disclosure are illustrative and explanatory and are intended to provide a detailed description of the present disclosure as claimed.

### BRIEF DESCRIPTION OF THE DRAWINGS

The accompanying drawings, which are included to provide a further understanding of the present disclosure and are incorporated in and constitute a part of this application, illustrate embodiment(s) of the present disclosure and together with the description serve to explain the principle of the present disclosure. In the drawings:

FIG. 1 is a block diagram schematically showing a material selection apparatus for vehicle parts using a BRS noise prediction algorithm, according to an embodiment of the present disclosure;

FIG. 2 is a block diagram schematically showing the configuration of a physical property data acquisition unit of the material selection apparatus for vehicle parts, according to an embodiment of the present disclosure;

FIG. 3 is a block diagram schematically showing the configuration of a BRS noise data acquisition unit of the material selection apparatus for vehicle parts, according to an embodiment of the present disclosure;

FIG. 4 is a flowchart showing a material selection method for vehicle parts using a BRS noise prediction algorithm, according to an embodiment of the present disclosure;

FIG. 5 is a flowchart showing a BRS noise data acquisition process in the material selection method for vehicle parts using the BRS noise prediction algorithm according to an embodiment of the present disclosure;

FIG. 6 is a graph showing the relationship between modulation time and sound (dB);

FIG. 7 is a flowchart showing a BRS noise prediction model generation process in the material selection method for vehicle parts using the BRS noise prediction algorithm according to an embodiment of the present disclosure;

FIG. 8 is a flowchart showing an optimal vehicle part material selection process in the material selection method for vehicle parts using the BRS noise prediction algorithm according to an embodiment of the present disclosure;

FIG. 9 is a graph showing an example of an objective function model generated using the material selection apparatus and method for vehicle parts using the BRS noise prediction algorithm according to an embodiment of the present disclosure; and

FIG. 10 is a graph showing the results of prediction of a BRS noise using the material selection apparatus and method for vehicle parts using the BRS noise prediction algorithm according to an embodiment of the present disclosure.

### DETAILED DESCRIPTION

Specific structural or functional descriptions of embodiments of the present disclosure disclosed in this specification are provided for illustrative purposes. Embodiments of the present disclosure may be realized in various forms, and should not be interpreted to be limited to the embodiments of the present disclosure disclosed in this specification.

Since the present disclosure may be variously modified and may have various forms, example embodiments are shown in the drawings and are described in detail in this specification. However, the present disclosure is not limited to the example embodiments, and it should be understood that the present disclosure includes all alterations, equivalents, and substitutes that fall within the idea and technical scope of the present disclosure.

It should be understood that, although the terms “first”, “second”, etc. may be used herein to describe various elements, corresponding elements should not be understood to be limited by these terms. Rather, these terms are used only to distinguish one element from another. For example, within the scope defined by the present disclosure, a first element may be referred to as a second element, and similarly, a second element may be referred to as a first element.

It should be understood that, when an element is referred to as being “connected to” or “coupled to” another element, the element may be directly connected to or coupled to the other element, or intervening elements may be present. In contrast, when an element is referred to as being “directly connected to” or “directly coupled to” another element, there are no intervening elements present. Other terms that describe relationships between elements, such as “between” and “directly between” or “adjacent to” and “directly adjacent to”, should be interpreted in the same manner. Similarly, “disposed on” may mean that an element is disposed directly on the surface of another element or disposed above another element so as to be spaced apart therefrom.

The terms used in this specification are provided only to explain specific embodiments, but are not intended to restrict the present disclosure. A singular representation may include a plural representation unless it represents a definitely different meaning from the context. It should be further understood that the terms “comprises”, “has” and the like, when used in this specification, specify the presence of stated features, numbers, steps, operations, elements, components, or combinations thereof, but do not preclude the presence or addition of one or more other features, numbers, steps, operations, elements, components, or combinations thereof.

Unless otherwise defined herein, all terms, including technical and scientific terms, used in this specification have the same meanings as those commonly understood by a person having ordinary skill in the art to which the present disclosure pertains. It should be further understood that terms, such as those defined in commonly used dictionaries, should be interpreted as having meanings consistent with their meanings in the context of the relevant art and the present disclosure, and should not be interpreted in an idealized or overly formal sense unless expressly so defined herein.

When a certain embodiment is differently realized, a function or operation specified in a specific block may be performed differently from the sequence specified in a flowchart. For example, two continuous blocks may be substantially simultaneously performed, or the blocks may be performed in reverse order depending on related functions or operations.

In the present disclosure, when a component, controller, device, element, unit, application, application portion, apparatus, or the like of the present disclosure is described as having a purpose or performing an operation, function, or the like, the component, controller, device, element, unit, application, application portion, apparatus, or the like should be considered herein as being “configured to” meet that purpose or to perform that operation or function. Each component, controller, device, element, unit, application, application portion, apparatus, and the like may separately embody or be included with a processor and a memory, such as a non-transitory computer readable media, as part of the apparatus.

Hereinafter, a material selection apparatus and method for vehicle parts using a BRS noise prediction algorithm according to embodiments of the present disclosure are described in detail with reference to the accompanying drawings.

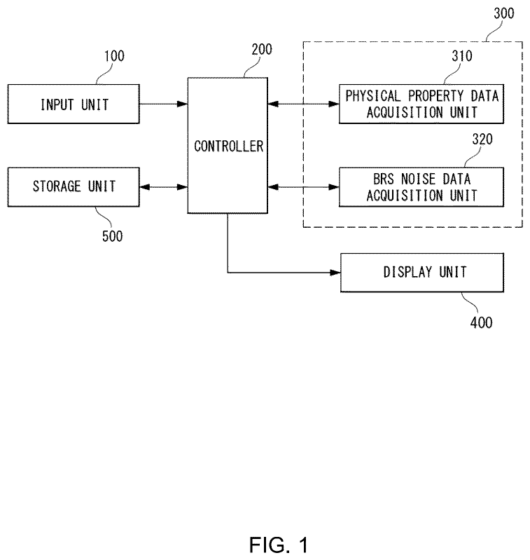

FIG. 1 is a block diagram schematically showing a material selection apparatus for vehicle parts using a BRS noise prediction algorithm according to an embodiment the present disclosure. As car manufacturing technology has advanced, strange sounds that were previously concealed by existing noise have begun to be heard more and more. A noise and a BRS noise may be generated as a car is driven. When external force, such as vibration or force, is applied to contact surfaces of adjacent parts, physical interaction may occur between the contact surfaces, resulting in noise. The BRS noise is an unwanted noise that occurs in a vehicle, and is also known as BSR (buzz, squeak, and rattle). The BRS noise in the vehicle does not affect the function of the vehicle, but may cause annoyance to occupants and reduce their satisfaction with the vehicle. A vibration BRS noise (BSR) test may be conducted to isolate the cause of the BRS noise in the vehicle.

Referring to FIG. 1, the material selection apparatus for vehicle parts using a BRS noise prediction algorithm, according to an embodiment of the present disclosure, includes an input unit 100, a controller 200, a data acquisition unit 300, a display unit 400, and a storage unit 500.

The input unit 100 may receive an external input signal for setting various conditions.

The data acquisition unit 300 may include a physical property data acquisition unit 310 and a BRS noise data acquisition unit 320. The physical property data acquisition unit 310 may acquire physical property information of a rubber material for vehicle parts through various tests. The BRS noise data acquisition unit 320 may acquire BRS noise data due to the friction between the rubber material for vehicle parts and a dissimilar opposing material while changing the surface shape, friction velocity, and friction load of the rubber material for vehicle parts.

The controller 200 may control the physical property data acquisition unit 310 and the BRS noise data acquisition unit 320 according to test conditions input through the input unit 100, may generate a Gaussian process regression model using extracted information, and may select the optimal rubber material for vehicle parts using the generated model. The controller 200 may refer to a central processing unit (CPU), a graphics processing unit (GPU), or a dedicated programmable processor on which methods according to embodiments of the present disclosure are performed. The controller 200 may be a programmable microprocessor that performs a data processing function to perform arithmetic and logical operations, an instruction execution function to interpret and execute program instructions, an input and output control function to receive input data from peripheral devices and transmit output results to the peripheral devices, and a memory access function to read data from a memory such as a register and write data to the memory.

The display unit 400 may display information according to the result of the operation of the controller in the form of characters, graphs, or sounds such that a user can visually or audibly recognize the information.

The storage unit 500 may store information acquired through the input unit 100, the physical property data acquisition unit 310, and the BRS noise data acquisition unit 320 and information about the Gaussian process regression model generated according to a control signal from the controller 200. The storage unit 500 may include at least one of a volatile storage medium or a non-volatile storage medium. For example, the storage unit 500 may include at least one of a read only memory (ROM) or a random access memory (RAM).

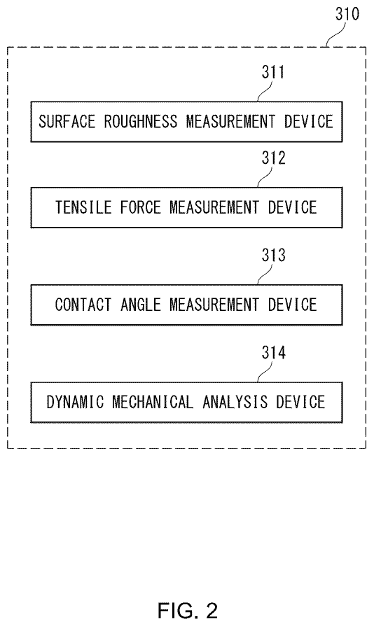

FIG. 2 is a block diagram schematically showing the configuration of the physical property data acquisition unit of the material selection apparatus for vehicle parts, according to an embodiment of the present disclosure.

The physical property data acquisition unit 310 may acquire physical property information of a rubber material for vehicle parts through various tests. The physical property data acquisition unit 310 may include a surface roughness measurement device 311, a tensile force measurement device 312, a contact angle measurement device 313, and a dynamic mechanical analysis device 314. The physical properties in the present disclosure may collectively refer to the electrical, magnetic, optical, mechanical, and thermal properties of the rubber material used for vehicle parts. The configuration shown in FIG. 2 is an embodiment for describing the present disclosure, and the present disclosure is not limited thereto.

The surface roughness measurement device 311 may measure the roughness of the surface of the rubber material for vehicle parts. The contact stiffness at the interface, which is an important factor in the occurrence of a BRS noise, is greatly affected by the area of the surface on which the contact is performed, and therefore the roughness of the surface is an important factor. A surface roughness measurement method may be selected according to the type of a surface to be measured and parameters to be measured. A mechanical method is a method of moving a probe along the surface and measuring the distance at which the probe hits the surface. An optical method is a method of illuminating a surface and measuring light reflected from the surface. An acoustic method is a method of transmitting sound waves to a surface and measuring the time it takes for the sound waves to be reflected. For example, the mechanical method is suitable for measuring rough surfaces, whereas the optical method is suitable for measuring fine surfaces.

The tensile force measurement device 312 may measure the mechanical properties of the rubber material for vehicle parts using a method standardized through tensile experiments. The tensile force measurement device 312 may measure the tensile strength, which is the maximum tensile stress that an object can withstand without breaking. The tensile strength may be expressed as tensile force/sectional area. The tensile force means the maximum force that a material can withstand before breaking, and the sectional area is the product of the width and length of the material. Newtons per millimeters squared (N/mm²) and kilogram force per millimeters squared (kgf/mm²) are used as the units for tensile strength. The tensile strength is measured to determine the characteristics of the material and is used when designing or manufacturing car parts. This device includes a material fixing device and a tensile force application device.

The contact angle measurement device 313 may measure the contact angle for comparing free energy of the surface of the rubber material for vehicle parts. The contact angle measurement device 313 may be a device that observes a process of liquid droplets forming on a solid surface and measures the contact angle when the droplets reach the solid surface. The possibility of the occurrence of the BRS noise at the interface is affected by hydrophilicity of the material surface or surface free energy. Contact angle refers to the angle that is formed when a liquid and a gas thermodynamically reach equilibrium on a solid surface. Contact angle indicates wettability of the solid surface and may be measured by standardized liquid droplets (sessile) formed on the solid surface. Contact angle is inversely proportional to surface energy. A low contact angle indicates high surface energy, whereas a high contact angle indicates low surface energy.

The dynamic mechanical analysis (DMA) device 314 measures the dynamic properties of the surface of the rubber material for vehicle parts. For stick-slip, which is a mechanism that generates an annoying friction noise, the dynamic properties of the material act as an important factor because the surface of the material is deformed at high velocity. The dynamic mechanical analysis device, which measures the viscoelasticity of the material, applies force and deformation to the material to analyze and acquire one or both of storage elasticity and “loss coefficient” of the material along with the effects of other factors such as temperature, time, and frequency.

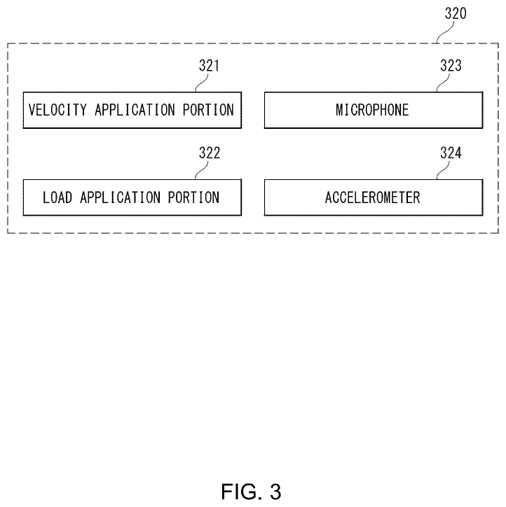

FIG. 3 is a block diagram schematically showing the configuration of the BRS noise data acquisition unit of the material selection apparatus for vehicle parts, according to an embodiment of the present disclosure. The BRS noise data acquisition unit 320 includes a velocity application portion (or simply “velocity application”) 321, a load application portion (or load “velocity application”) 322, a microphone 323, and an accelerometer 324. The velocity application 321 may reduce the distance between the rubber material for vehicle parts and a dissimilar opposing material that are spaced apart from each other within a predetermined time to generate horizontal friction between the two materials. The dissimilar opposing material may include aluminum, glass fiber reinforced plastic, and carbon fiber reinforced plastic.

The load application 322 may apply pressure to generate vertical friction between the rubber material for vehicle parts and the dissimilar opposing material.

The microphone 323 may measure the sound generated between the rubber material for vehicle parts and the dissimilar opposing material by the frictional force that is changed and provided through the velocity application portion 321 and/or the load application portion 322.

The accelerometer 324 may measure the magnitude of the vibration generated between the rubber material for vehicle parts and the dissimilar opposing material by the frictional force that is changed and provided through the velocity application portion 321 and/or the load application portion 322. In an example, a rattle noise may refer to an impact noise generated as the result of the regions of parts in contact with each other colliding with each other due to vibration. The microphone 323 may be used to evaluate the loudness of the sound, and has the disadvantage of requiring the construction of a silent facility, whereas the accelerometer may objectively determine the physical properties of the material because it is possible to easily perform spectrum analysis that shows the vibration frequency characteristics without the need for separate facilities.

The controller 200 may determine (e.g., calculate) psychoacoustic annoyance, which is an affective quality index for each dissimilar opposing material, based on BRS noise data provided by the BRS noise data acquisition unit 320 and may reflect the same in output data of the model.

In addition, although not specifically shown, a fixing device for fixing each material used in tests, such as a jig, a driving means for providing power, such as an actuator, and a measurement device for measuring the magnitude of the pressure applied to materials, such as a load cell, may be provided.

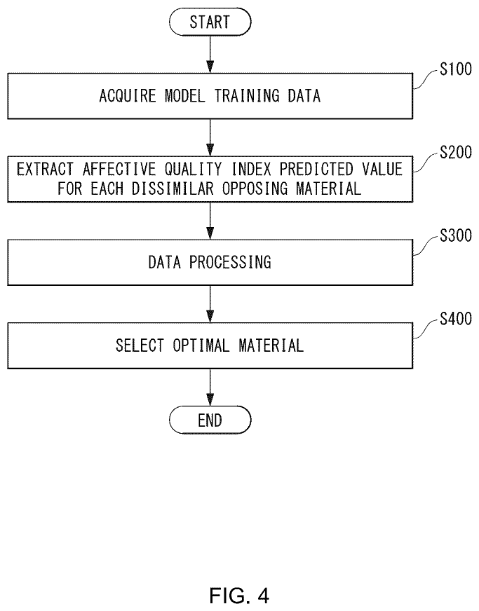

FIG. 4 is a flowchart showing a material selection method for vehicle parts using a BRS noise prediction algorithm, according to an embodiment of the present disclosure.

In an operation S100, data required to train a BRS noise prediction model of a material for vehicle parts are acquired.

Once training data are generated through various tests, a Gaussian process regression model is generated using Bayesian optimization for the acquired training data.

In an operation S200, once a BRS noise prediction machine learning model is determined, an affective quality index for each dissimilar material is predicted using the generated model. In an operation S300, data processing may be performed to evaluate the generated model and to synthetize the affective quality index predicted values through a model predicted value and a database to select the optimal material in an operation S400.

In the present disclosure, “training” refers to the process of feeding the distribution of data into the model, and “testing/evaluation” refers to the comparison of how many correct answers (y) were given when the data (x) was input into the distribution (function) that the model learned.

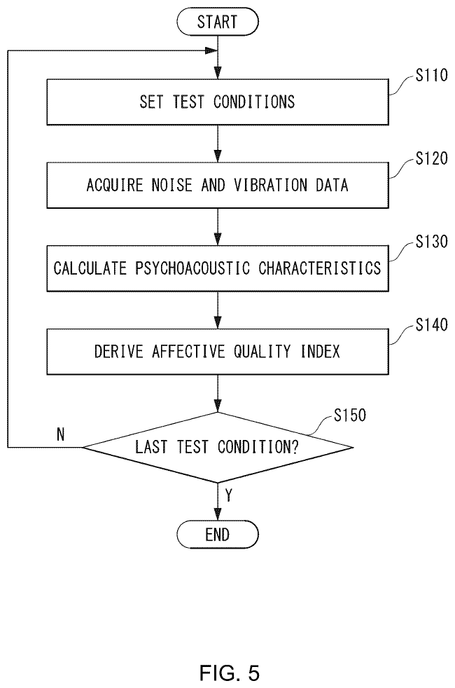

FIG. 5 is a flowchart showing a BRS noise data acquisition process in the material selection method for vehicle parts using the BRS noise prediction algorithm, according to an embodiment of the present disclosure.

In an operation S110, test conditions including the surface shape, friction velocity, and friction load of the rubber material for vehicle parts are set.

In an operation S120, noise and vibration data generated upon friction with the dissimilar opposing material are acquired. BRS noise data reflecting the physical properties and the test conditions of the car part material are acquired through the physical property data acquisition unit 310 and the BRS noise data acquisition unit 320. The relative position, insertion direction, clearance and step, and fastening angle of coupling parts that are coupled to each other are adjusted to measure the noise generated between the parts.

In an operation S130, psychoacoustic characteristics are determined (e.g., calculated) using the acquired noise data. The psychoacoustic characteristics may be perceptual characteristics for auditory stimuli. The physical quantities measured by equipment, such as the directional microphone 323 and the accelerometer 324, may differ from the intensity of annoyance sensed by the actual human body's sensory organs. Therefore, in order to analyze the effect of an annoying friction noise on affective quality, it may be necessary to use an affective quality index determined (e.g., calculated) based on psychoacoustic characteristics. The psychoacoustic factors of an unpleasant noise are explained by the combination of auditory sensations caused by the physical characteristics of the noise. These factors are called psychoacoustic annoyance.

In the test for the occurrence of a BRS noise from a dissimilar opposing material, the controller 200 may conduct a friction test for each dissimilar opposing material by varying environmental factors such as surface shape, friction velocity, and friction load, to measure BRS noise data for each test. The controller 200 may determine (e.g., calculate) the psychoacoustic annoyance, which is an affective quality index, based on the BRS noise data.

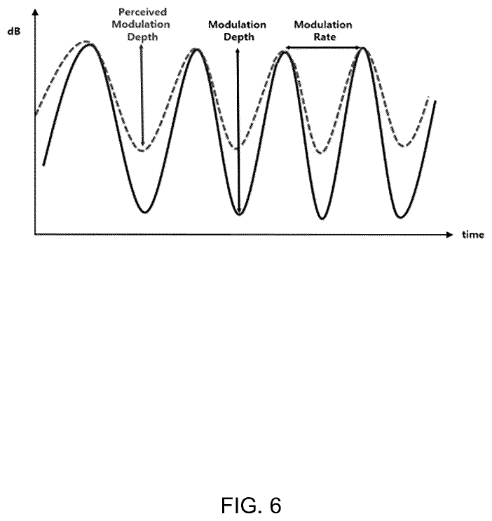

The affective quality index may be derived or determined by combining psychoacoustic characteristics. Psychoacoustic annoyance is an index that numerically expresses human's subjective annoyance with noise. The controller 200 may determine (e.g., calculate) psychoacoustic characteristics including loudness, sharpness, fluctuation, and roughness of sound from an acoustic signal. The controller 200 may determine (e.g., derive) the affective quality index by combining the determined psychoacoustic characteristics. In an example, the magnitude of variability (e.g., vacillations (vacil)) and roughness (e.g., asperities (asper)) are related to the acoustic properties of the modulation of the pitch of the sound. Accordingly, fluctuation strength or roughness may be determined depending on the change in the pitch of the sound per second (level rises and falls/sec). When the frequency is 20 Hz or less, it is called fluctuation strength (vacil), and when the frequency is between 20 Hz and 300 Hz, it is called roughness (asper). As shown in the graph of FIG. 6, the modulation depth may be represented by a solid line, and the perceived modulation depth may be represented by a dotted line.

The controller 200 may determine an affective quality index that represents the magnitude of psychoacoustic annoyance using Mathematical expression 1 below.

$$PA = {N}_{5} ( 1 + \sqrt{( {w}_{S}^{2} + {w}_{FR}^{2} )} ) \qquad ( Mathematical expression 1 )$$

In Mathematical expression 1, “W_{S}” is the same as Wₛ=0.25(S−1.75)log(N₅+10), and “W_{FR}” is the same as W_{FR}=2.18(0.4F+0.6R)/(N₅)^{0.4}.

The symbol “N₅” means loudness, “S” means sharpness, “F” means fluctuation, and “R” indicates roughness.

The affective quality index may be generated for each dissimilar opposing material. For example, an affective quality index for aluminum, an affective quality index for GFRP, and an affective quality index for CFRP may be generated.

In an operation S140, the environmental factors of the BRS noise generation friction test are used and learned as input data of the BRS noise prediction machine learning model, and the affective quality index of each dissimilar opposing material is used and learned as output data of the model.

In an operation S150, it is determined whether all conditions have been tested, and, based on the determination, new test conditions are set or acquisition of BRS noise data is finished.

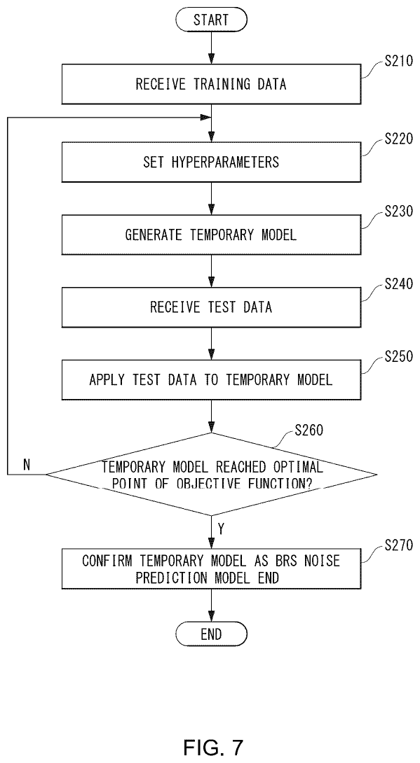

FIG. 7 is a flowchart showing a BRS noise prediction model generation process in the material selection method for vehicle parts using the BRS noise prediction algorithm, according to an embodiment of the present disclosure. The BRS noise prediction model is generated using Bayesian optimization in a Gaussian process regression model generation step.

Gaussian process regression is a method of modeling the correlation between continuous data by assuming that data distribution is normal distribution, and Bayesian optimization is an iterative process of estimating the distribution of a function using a probability model to find the optimal value of an objective function and determining the next search point through an acquisition function.

Due to the nature of vibration noise experiments, errors between experiments are relatively large, and since friction characteristics between dissimilar materials are dealt with, various factors are generated in a complex manner, and therefore a suitable Gaussian process regression model is used. The training data obtained in a training data acquisition step are input to the model, and the input data are classified into training and test sets, wherein the training set is used for model training and the test set is used for checking the optimization of the model.

The terms used in a Gaussian process are defined as follows.

Process: The Gaussian process may be regarded as modeling a “probabilistic process.” In other words, this is a probability model used to describe the relationship between inputs and outputs.

Probability distribution: The Gaussian process defines the probability distribution for all input values. It is assumed that the output value follows a Gaussian distribution for each input value. Therefore, the Gaussian process characterizes the probability distribution through the mean and covariance (or kernel).

Kernel: One of the key parts of the Gaussian process is a kernel function. The kernel function defines the correlation between input values. This is used to measure the similarity between input values and to determine the correlation of output values.

Inference: The Gaussian process is used to infer the output value for a given input value. The mean and variance are determined (e.g., calculated) based on existing observed values, and a predicted value and the uncertainty of prediction are provided therethrough. The prediction is useful in both regression and classification problems.

Hyperparameters: The Gaussian process has hyperparameters of the kernel function. The hyperparameters are tuned during training of the model and are optimized to improve the model's suitability.

Stochastic prediction: The Gaussian process is a stochastic model, which means that the Gaussian process provides uncertainty of a predicted value. Stochastic prediction determines reliability of the predicted value.

In an operation S210, the training data are received to generate the BRS noise prediction model.

In an operation S220, the hyperparameters, such as the type of kernel and the size of the kernel, used in the model are set using the received training data.

A Gaussian process regression temporary model is generated based on the set hyperparameters (S230).

In an operation S240, test data are received to set hyperparameters, and, in an operation S250, the test data are applied to the Gaussian process regression temporary model based on the set hyperparameters.

In an operation S260, it is determined whether the model using the test data reaches the optimal point of the objective function, and if the model does not reach the optimal point of the objective function, the process returns to the step of setting the hyperparameters again by exploring the design space of the hyperparameters in the operation S220. The design space of the hyperparameters may be set so as to be suitable for a dissimilar material friction environment.

The hyperparameters may be optimized such that the model reaches the optimal point of the objective function based on the Gaussian process regression. In a Bayesian optimization method, a Gaussian process model for an unknown objective function may be constructed using sampled training data, the next point that is expected to minimize the uncertainty of the objective function or maximize a predicted value of the function is selected, data are sampled at that point, and the maximum value of the objective function is determined (e.g., calculated) through an iteration process that updates the Gaussian process model. The hyperparameters may be sequentially selected, a combination of hyperparameters is presented as training data to accelerate the training process, and the temporary model that reaches the optimal point of the objective function using Gaussian process regression may be confirmed as a BRS noise prediction machine learning model, whereby it is possible to predict the possibility of reaching the objective function.

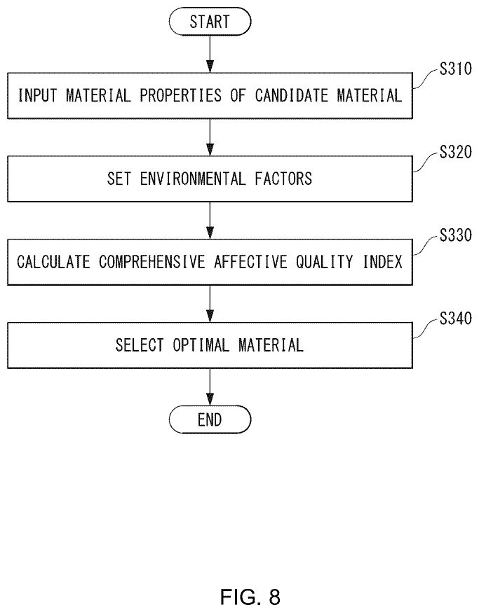

FIG. 8 is a flowchart showing an optimal vehicle part material selection process in the material selection method for vehicle parts using the BRS noise prediction algorithm, according to an embodiment the present disclosure.

In an operation S310, the material property information of a plurality of candidate rubber materials for vehicle parts is input through the input unit.

In an operation S320, environmental factors considering the conditions of use are input to the BRS noise prediction model.

In an operation S330, a comprehensive affective quality index is determined (e.g., calculated) based on a plurality of affective quality indices for each dissimilar opposing material.

In an operation S340, the optimal material is selected through the comprehensive affective quality index for each of the plurality of candidate rubber materials for vehicle parts.

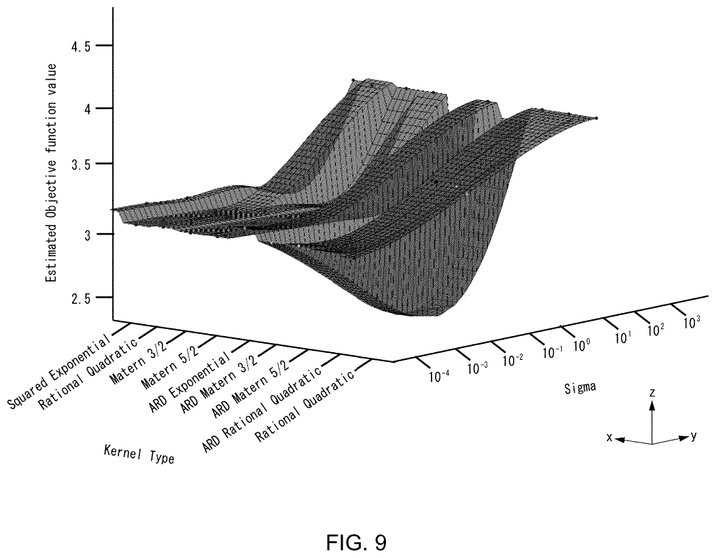

FIG. 9 is a graph showing an example of an objective function model generated using the material selection apparatus and method for vehicle parts using the BRS noise prediction algorithm, according to an embodiment of the present disclosure. The x-axis represents the type of a kernel function (Kernel Type), the y-axis represents a sigma value (sigma), and the z-axis represents an estimated objective function value.

The kernel function type and the initial value of sigma (σ) have a significant impact on the results of the Gaussian process regression. Therefore, the form and values that reflect the characteristics of the data are selected to perform Bayesian optimization.

The predicted value using the Gaussian process regression may be expressed as follows:

$$P ( y \vert f , X ) \sim N ( y \vert H β + f , {σ}^{2} I ) ,$$

where f is a kernel function, which may use various function forms, σ represents the optimized standard deviation value, and Hβ is a value related to a base function, which has little effect on the results of the Gaussian process regression and is not used in Bayesian optimization.

In the objective function model according to the example, a total of nine kernel function forms were explored. The kernel functions used are as follows.
1. Squared Exponential Kernel
2. Rational Quadratic Kernel
3. Matern 3/2 Kernel
4. Matern 5/2 Kernel
5. ARD Exponential Kernel
6. ARD Matern 3/2 Kernel
7. ARD Matern 5/2 Kernel
8. ARD Rational Quadratic Kernel
9. Rational Quadratic Kernel

In an embodiment, sigma (σ), which represents the optimized standard deviation value, is selected from a range of values between 10⁻³ and 10³ to proceed with Bayesian optimization.

Function evaluation was performed 30 times using 5-fold cross validation. K-fold cross validation is a validation method of measuring the performance of a model on all data while systematically changing a set.

In order to measure the accuracy of the model, the model is trained with the first fold as the test data to calculate or otherwise determined the accuracy, the second fold as the test data to calculate or otherwise determine the accuracy, and the third fold as the test data to calculate or otherwise determine the accuracy, which is repeated up to the fifth fold.

As a result of optimization, sigma (σ) returns the Matern 3/2 Kernel function of 1.399.

The estimated objective function value represents the mean square error of the true value and the predicted value used as the objective function of Bayesian optimization. The mean square error may be expressed by Mathematical expression 2.

$$MSE = \frac{1}{n} {\sum }_{i = 1}^{n} {( {Y}_{i} - {\hat{Y}}_{i} )}^{2} \qquad ( Mathematical expression 2 )$$

In Mathematical expression 2, Yᵢ indicates the true value, and Ŷᵢ indicates the predicted value through the Gaussian process regression.

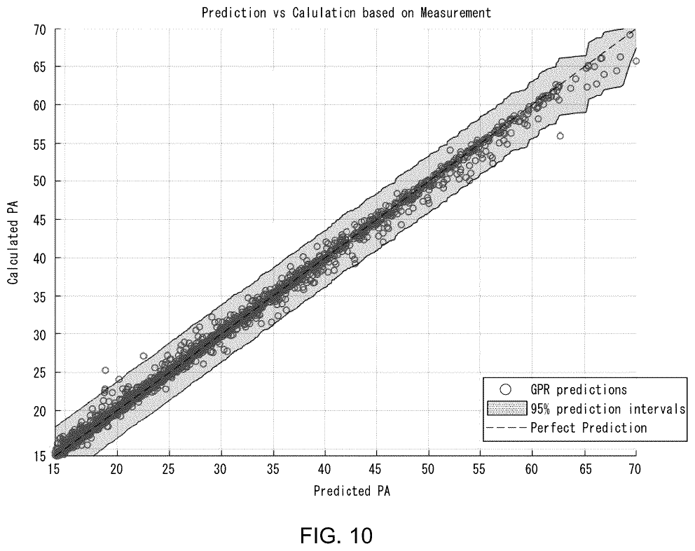

FIG. 10 is a graph showing the results of prediction of a BRS noise using the material selection apparatus and method for vehicle parts using the BRS noise prediction algorithm, according to an embodiment of the present disclosure.

A Gaussian process regression model suitable for the data was found through Bayesian optimization, and the results show that the true value and the predicted value are very similar.

As described above, in the material selection apparatus and method for vehicle parts using the BRS noise prediction algorithm according to embodiments of the present disclosure, it is possible to identify the range of material properties and environmental factors in the training database based on the design criteria using the predicted value of the machine learning model, whereby it is possible to select the optimal material. In addition, it is possible to improve product quality and to reduce design costs by reflecting the optimal material in the design conditions of the parts through the BRS noise prediction model.

As is apparent from the above description, in the material selection apparatus and method for vehicle parts using the BRS noise prediction algorithm according to embodiments of the present disclosure, it is possible to predict the BRS noise signal and the affective quality index value that may occur according to the conditions through the machine learning model, to identify the principle of BRS noise occurrence at the same time, and to identify the range of the material properties and environmental factors in the training database according to the design criteria using the predicted value of the machine learning model, whereby it is possible to select the optimal material.

Although example embodiments of the present disclosure are described above with reference to the accompanying drawings, those having ordinary skill in the art should appreciate that various modifications and alterations are possible without departing from the idea and field of the present disclosure set forth in the appended claims.

What is claimed is:

1. A material selection apparatus for vehicle parts using a BRS (Buzz, Rattle, Squeak) noise prediction algorithm, the material selection apparatus comprising:
an input unit configured to receive an external input signal for setting one or more conditions;
a physical property data acquisition unit configured to acquire physical property information of a rubber material through one or more tests;
a BRS noise data acquisition unit configured to acquire BRS noise data descriptive of BRS noise due to friction between the rubber material and a dissimilar material while changing a surface shape, friction velocity, and friction load of the rubber material for vehicle parts;
a controller configured to
control the physical property data acquisition unit and the BRS noise data acquisition unit according to test conditions input via the input unit, and
select an optimal rubber material using a Gaussian process regression model, wherein the optimal rubber material is optimal according to the Gaussian process regression model;
a display unit configured to display information according to a result of operation of the controller; and
a storage unit configured to store information acquired through the input unit, the physical property data acquisition unit, and the BRS noise data acquisition unit and information associated with the Gaussian process regression model.

2. The material selection apparatus according to claim 1, wherein the physical property data acquisition unit includes at least one of:
a surface roughness measurement device configured to measure roughness of a surface of the rubber material;
a tensile force measurement device configured to measure mechanical properties of the rubber material;
a contact angle measurement device configured to measure a contact angle for comparing free energy of the surface of the rubber material; or
a dynamic mechanical analysis device configured to measure dynamic properties of the surface of the rubber material.

3. The material selection apparatus according to claim 2, wherein the BRS noise data acquisition unit includes:
a velocity application configured to generate horizontal friction between the rubber material and the dissimilar material;
a load application configured to generate vertical friction between the rubber material and the dissimilar material;
a microphone configured to measure sound generated between the rubber material and the dissimilar material by frictional force that is changed and provided by the velocity application and/or the load application; and
an accelerometer configured to measure vibration generated between the rubber material and the dissimilar material by the frictional force that is changed and provided by the velocity application and/or the load application.

4. The material selection apparatus according to claim 1, wherein the dissimilar material comprises at least one of aluminum, glass fiber reinforced plastic, or carbon fiber reinforced plastic.

5. The material selection apparatus according to claim 4, wherein the controller is configured to:
determine psychoacoustic annoyance based on the BRS noise data provided by the BRS noise data acquisition unit, wherein the psychoacoustic annoyance is an affective quality index for each dissimilar material; and
reflect the psychoacoustic annoyance in output data of the Gaussian process regression model.

6. A material selection method for vehicle parts, the material selection method comprising:
acquiring training data to train a BRS (Buzz, Rattle, Squeak) noise prediction model of a material;
generating a Gaussian process regression model using Bayesian optimization for the acquired training data;
extracting affective quality index predicted values for respective dissimilar materials using the Gaussian process regression model; and
selecting an optimal material based on the affective quality index predicted values, wherein the optimal rubber material is optimal according to the Gaussian process regression model.

7. The method according to claim 6, wherein acquiring data required to train the BRS noise prediction model includes:
performing a test for acquiring physical property information of a rubber material; and
performing a test for acquiring friction noise data for a dissimilar material.

8. The material selection method according to claim 7, wherein the physical property information includes at least one of mechanical properties of the rubber material, roughness of a surface of the rubber material, a contact angle of the surface, or dynamic properties of the surface.

9. The material selection method according to claim 7, wherein the dissimilar m comprises at least one of aluminum, glass fiber reinforced plastic, or carbon fiber reinforced plastic.

10. The material selection method according to claim 7, wherein performing the test for acquiring friction noise data for the dissimilar material includes:
acquiring noise and vibration data generated based on friction between the rubber material and the dissimilar material while changing a surface shape, friction velocity, and friction load of the rubber material;
determining psychoacoustic characteristics based on the acquired noise data, wherein the psychoacoustic characteristics are perceptual characteristics for auditory stimuli; and
combining the psychoacoustic characteristics to determine an affective quality index.

11. The material selection method according to claim 10, wherein the psychoacoustic characteristics include at least one of loudness, sharpness, fluctuation, or roughness of sound.

12. The material selection method according to claim 6, wherein generating the Gaussian process regression model includes:
receiving the acquired training data;
setting hyperparameters;
generating a temporary Gaussian process regression model based on the set hyperparameters;
receiving test data;
applying the test data to the temporary Gaussian process regression model to determine whether the temporary Gaussian process regression model has reached an optimal point of an objective function; and
returning to setting the hyperparameters through search of a design space of the hyperparameters when the temporary Gaussian process regression model has not reached the optimal point and confirming the temporary Gaussian process regression model that reaches the optimal point as a BRS noise prediction machine learning model.

13. The material selection method according to claim 12, wherein extracting the affective quality index predicted values for respective dissimilar materials includes:
acquiring material property information of a plurality of candidate rubber materials;
acquiring environmental factors considering conditions of use;
determining a comprehensive affective quality index based on a plurality of affective quality indices for each dissimilar material; and
selecting an optimal material based on the comprehensive affective quality index for each of the plurality of candidate rubber materials.
